(19) United States
(12) Patent Application Publication
(10) Pub. No.: US 2006/0054279 A1
(43) Pub. Date: Mar. 16, 2006

(54) Apparatus for the optimization of atmospheric plasma in a processing system

(76) Inventors: Yunsang Kim, San Jose, CA (US); Andras Kuthi, Thousand Oaks, CA (US)

Correspondence Address: IPSG, P.C., P.O. BOX 700640, SAN JOSE, CA, 95170-0640, US

(21) Appl. No.: 10/938,680

(22) Filed: Sep. 10, 2004

(51) Int. Cl. H01L 21/306

(52) U.S. Cl. 156/345.33; 156/345.29

(57) ABSTRACT

An apparatus for cleaning a substrate in a reactive ion etch process is disclosed. The apparatus is configured to produce an atmospheric plasma using a RF generation device. The apparatus includes a plasma forming chamber including a cavity defined by a set of interior chamber walls comprised of a dielectric material. The apparatus also includes an atmospheric plasma generated by the RF generation device, the atmospheric plasma protruding from a first end of the cavity to clean the substrate.

### BACKGROUND OF THE INVENTION

The present invention relates in general to substrate manufacturing technologies and in particular to apparatus for the optimization of atmospheric plasma in a plasma processing system.

In the processing of a substrate, e.g., a semiconductor substrate or a glass panel such as one used in flat panel display manufacturing, plasma is often employed. As part of the processing of a substrate for example, the substrate is divided into a plurality of dies, or rectangular areas, each of which will become an integrated circuit. The substrate is then processed in a series of steps in which materials are selectively removed (etching) and deposited. Subsequently, control of the transistor gate critical dimension (CD) on the order of a few nanometers is a top priority, as each nanometer deviation from the target gate length may translate directly into the operational speed of these devices.

Areas of the hardened emulsion are then selectively removed, causing components of the underlying layer to become exposed. The substrate is then placed in a plasma processing chamber on a substrate support structure comprising a mono-polar or bi-polar electrode, called a chuck or pedestal. Appropriate etchant source are then flowed into the chamber and struck to form a plasma to etch exposed areas of the substrate.

Due to the complexity of process integration in semiconductor fabrication, the substrate cleaning process is very critical to enhance device yield, since after each process step may be a potential source of such contaminants (e.g., particles, metallic impurities, trace organic contaminants, etc.) which may lead to defect formation and device failure.

In general, wet cleaning is the most frequently repeated step in any substrate manufacturing sequence because of its effectiveness in reducing the presence of contaminants. Often a set of cleaning chambers is attached to plasma processing chamber in order to improve productivity. Hydrogen peroxide-based chemistry is the most prevalent cleaner in the semiconductor industry worldwide. For example, substrates may be sequentially immersed for several minutes in an NH₄OH—H₂O₂—H₂O mixture (SC-1) and an HCl—H₂O₂—H₂O mixture (SC-2) at elevated temperatures, and then in dilute HF at room temperature.

Among the most common types of cleaning methods is single-substrate spin cleaning. For example, a spin cleaning system may function by alternately applying ozonated water and dilute HF onto a substrate surface for a few seconds, a cycle that can be repeated as many times as necessary until the surface attains the required level of cleanliness. Following the last dilute-HF treatment, either DI water is applied to the substrate to obtain a hydrophobic silicon surface or ozonated water is applied to obtain a hydrophilic silicon surface. Then spin drying takes place in a nitrogen atmosphere to prevent spot formation on the patterned substrate.

For example, in a typical modern substrate manufacturing process, there may be about 54 cleaning steps in the front end of line (FEOL) and 45 cleaning steps in the back end of line (BEOL). The pre-diffusion cleans (20 steps) and the post-ash cleans (30 steps) typically include some variant of the RCA cleaning process.

RCA is a wet-chemical silicon substrate cleaning process based on hydrogen peroxide solutions. In general, substrates are cleaned in two steps, the first using an aqueous mixture of hydrogen peroxide and ammonium hydroxide, the second using a mixture of hydrogen peroxide and HCl. The process can be implemented by a variety of techniques using various systems.

Referring now to FIG. 1, a simplified substrate manufacturing process is shown. Initially, a set of LP (low pressure) oxides, nitrides, poly-Si, and some barrier materials are deposited on the substrate at step 102. Next, a set of substrate masks is patterned in a lithography process, at step 104. The substrate in then etched and further patterned using chemically dominant etch process, at step 106. A wet chemical cleaning process then commonly occurs at step 108. This process can take up to 2 hours per substrate.

With smaller device geometries, the number of cleaning steps increases and is reaching >100 steps in some recent process flows. Increasing the number of cleaning cycles contributes to additional cycle time, cumulative silicon and oxide loss, and damage to fragile structures. Therefore, a shorter, more efficient cleaning process is critical to achieving high-productivity device manufacturing. In addition, increasing concerns about ground water and air pollution, greenhouse gases, and related health and safety issues have severely restricted the use of common volatile organic solvents in wet-chemical cleaning processes.

In view of the foregoing, there are desired improved apparatus for the optimization of atmospheric plasma in a plasma processing system.

### SUMMARY OF THE INVENTION

The invention relates, in one embodiment, to an apparatus for cleaning a substrate in a reactive ion etch process is disclosed. The apparatus is configured to produce an atmospheric plasma using a RF generation device. The apparatus includes a plasma forming chamber including a cavity defined by a set of interior chamber walls comprised of a dielectric material. The apparatus also includes an atmospheric plasma generated by the RF generation device, the atmospheric plasma protruding from a first end of the cavity to clean the substrate.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a simplified diagram of substrate manufacturing process;

FIG. 2 illustrates a simplified diagram of a generic DC plasma cleaning device;

FIG. 3 illustrates a simplified diagram of a RF plasma cleaning device;

FIGS. 4A-B illustrate a set of RF micro-hollow cathode discharge chambers for cleaning a substrate, according to one embodiment of the invention;

FIG. 5 illustrates the RFMHCD cleaning device of FIG. 4, from a view that is parallel to the discharge chambers, according to one embodiment of the invention; and

FIG. 6 illustrates a simplified substrate manufacturing process, according to one embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

While not wishing to be bound by theory, the inventor believes that atmospheric plasma can be used in a reactive ion etch (RIE) process to optimally clean a substrate.

In one embodiment, optimized atmospheric plasma can be focused on a specific area on the substrate with a substantially high etching rate.

In another embodiment, localized optimized atmospheric plasma is integrated with an in-situ wet cleaning process.

In another embodiment, localized optimized atmospheric plasma is generated by a hole with a length substantially equal to the mean free path of the plasma gas at the system's operating pressure.

In another embodiment, an atmospheric plasma can be created by injecting reactant gases into a set of RF dielectric micro-hollow cathode discharge chambers (or cavities).

In another embodiment, the set of RF dielectric micro-hollow cathode discharge chambers comprise a dielectric insulator.

As previously stated, the cleaning process is very critical to enhance device yield, since after each process step may be a potential source of such contaminants (e.g., particles, metallic impurities, trace organic contaminants, etc.) which may lead to defect formation and device failure. However, wet cleaning approaches tend to be costly and time consuming, often comprising many process steps and the handling of hazardous liquid chemicals.

An alternative to wet cleaning is to dry etch the substrate by the use of a conventional low-pressure plasma, typically ranging in pressure from high vacuum (<0.1 mTorr) to several Torr. The primary advantage of plasma cleaning is that it is an “all-dry” process, generates minimal effluent, does not require hazardous pressures, and is applicable to a wide variety of vacuum-compatible materials, including silicon, metals, glass, and ceramics. For example, a common dry etch process involves pure ion etching, or sputtering, in which ions are used to dislodge material from the substrate (e.g., oxide, etc.). Commonly an inert gas, such as Argon, is ionized in a plasma and subsequently accelerate toward a negatively charged substrate. Pure ion etching is both isotropic (i.e., principally in one direction) and non-selective. That is, selectivity to a particular material tends to be very poor, since the direction of the ion bombardment is mostly perpendicular to the wafer surface in plasma etch process. In addition, the etch rate of the pure ion etching is relatively low, depending generally on the flux and energy of the ion bombardment. Pure ion etching is widely used in dielectric thin film applications to taper the gap opening.

Another common dry etch process involves reactive ion etch (RIE), also called ion-enhanced etching. RIE combines both chemical and ion processes in order to remove material from the substrate (e.g., photoresist, BARC, TiN, Oxide, etc.). Generally ions in the plasma enhance a chemical process by striking the surface of the substrate, and subsequently breaking the chemical bonds of the atoms on the surface in order to make them more susceptible to reacting with the molecules of the chemical process.

However, conventional low-pressure plasma processes often require sophisticated components, such has advanced vacuum systems, and hence have relatively high costs. Subsequently, conventional low-pressure plasma technology is typically used where there exists no other less costly way to process substrate material.

One solution has been the use of atmospheric (or high pressure) plasmas. For example, a DC plasma may be created by an electrical discharge between two electrodes, using a plasma support gas such as Ar. As electrons are lost to the anode, they are replenished by the release of secondary electrons at an exposed cathode. However, as the density of electrically charged species (i.e., ions, etc.) in the plasma increases (typically above 2%), the likelihood of destructive arcing at the exposed electrode also increases. Hence, most atmospheric plasma processes typically comprise mostly non-electrically charged species, such as He, which limit ionization.

An arc is generally a high power density short circuit which has the effect of a miniature explosion. When arcs occur on or near the surfaces of the target material or chamber fixtures, substantial damage can occur, such as local melting. Plasma arcs are generally caused by low plasma impedance which results in a steadily increasing current flow. If the resistance is low enough, the current will increase indefinitely (limited only by the power supply and impedance), creating a short circuit in which all energy transfer takes place. This may result in damage to the substrate as well as the plasma chamber. Subsequently, to inhibit arcing, a relatively high plasma impedance generally must be maintained, such as by limiting the rate of ionization in the plasma.

However, many plasma cleaning processes necessitate the use of RIE (and hence ions) that increases the likelihood of arcing. For example, cleaning an oxide film generally requires over 5% of an active ion species, such as CF₄, SF₆, C₂F₆, and O₂; cleaning photoresist and residues generally requires over 5% of an active ion species such as CF₄, SF₆, C₂F₆, N₂ with O₂; and cleaning poly-si generally requires over 5% of an active ion species, such as C1₂, CF₄, SF₆, C₂F₆ with O₂.

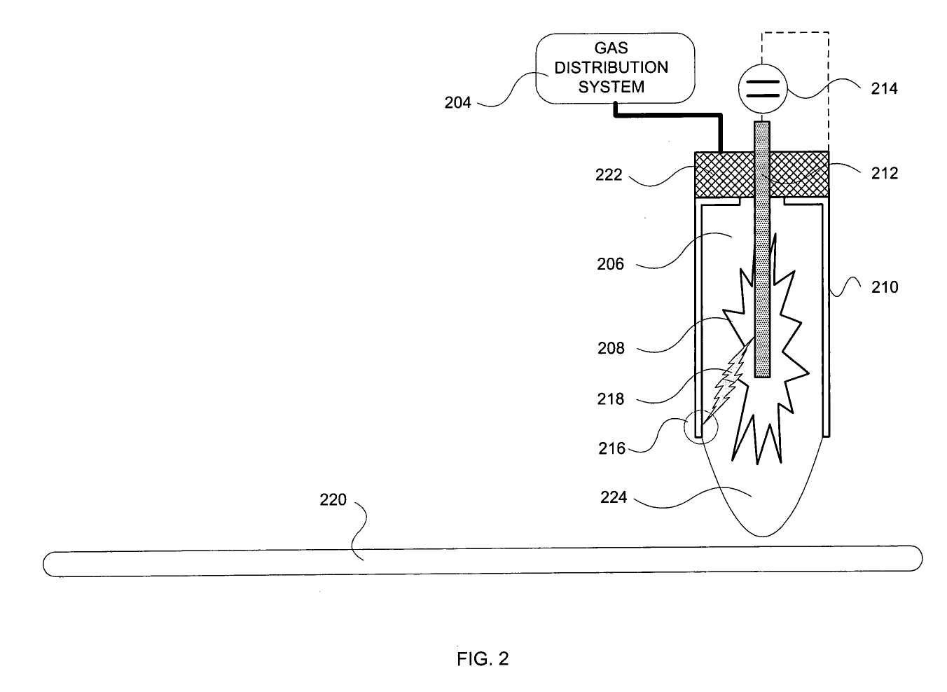

Referring now to FIG. 2, a simplified diagram of a generic DC plasma cleaning device is shown. Generally, an appropriate set of gases is flowed into chamber 206 from gas distribution system 204. At one end of chamber 206 there is generally an electrically insulating material 222. At the other end, cavity 206, defined by cathode 210, produces a plasma to etch substrate 220. Electrical insulator 222 which seals one end of the apparatus is made of any suitable electrically insulating material and typically a plastic. Electrical insulator 222 generally has a hole or bore extending at its center, for receiving metal anode 212. Metal anode 212 is generally fabricated of any convenient metal, with stainless steel being convenient. A high voltage D.C. power supply 214 typically outputs a substantial amount of energy. However, as previously described, etchants with substantial amounts of electrically charged species, such as RIE, will increase the likelihood of destructive arcing 218, that may subsequently damage substrate 220 or chamber 206, such as at location 216. Hence, DC plasma cleaning devices are not generally suitable for RIE applications.

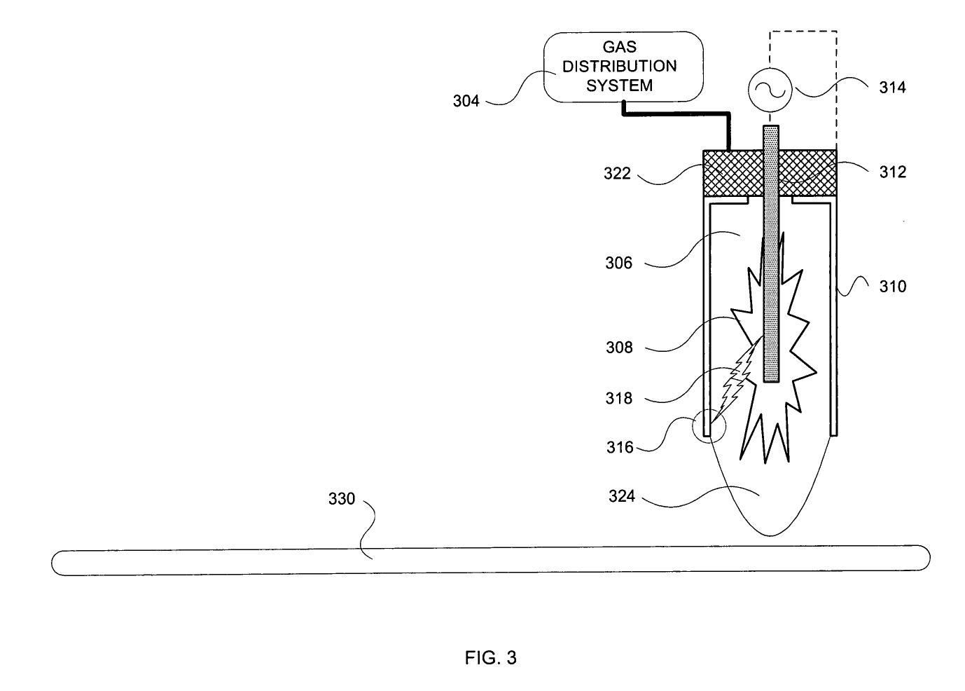

Referring now to FIG. 3, a simplified diagram of a conventional RF plasma cleaning device is shown. In general, because the plasma discharge is RF driven and weakly ionized, electrons in the plasma are not in thermal equilibrium with ions. That is, while the heavier ions efficiently exchange energy by collisions with the background gas (e.g., argon, etc.), electrons absorb the thermal energy. Because electrons have substantially less mass than that of ions, electron thermal velocity is much greater than the ion thermal velocity. This tends to cause the faster moving electrons to be lost to surfaces within the plasma processing system, subsequently creating positively charged ion sheath which can be used to clean substrate 324. Ions that enter the sheath are then accelerated.

At one end of chamber 306 there is generally an electrically insulating material 322. At the other end, cavity 306, produces a plasma to etch substrate 320. As before in FIG. 2, appropriate plasma processing gases are then flowed into the chamber 306 and ionized by an exposed electrode 312, commonly coupled to a RF source 314. The electrode 312 functions, similar in purpose to a transformer, that induces a time-varying voltage and potential difference in the plasma processing gases to create a plasma by successively turning the current on and off in the primary coil.

As previously described, the use of RIE (and hence ions) increases the likelihood of arcing 318 that may subsequently damage substrate 320 or chamber 306, such as at point 316. Hence, RF plasma cleaning devices are not generally suitable for RIE applications.

In a non-obvious fashion, a dielectric layer may be employed in a RF plasma cleaning device substantially reduce the risk of arcing. In one embodiment, the RF plasma cleaning device is an insulated RF micro-hollow cathode discharge (RFMHCD) cleaning device. As generally understood in the art, RFMHCD devices generally comprise relatively small diameter chambers, often less than 10 mils. They generally allow the production of stable atmospheric plasma with a relatively high power density (i.e., high electron energy, etc.) in a relatively small space.

In another embodiment, each discharge chamber (cavity) includes a dielectric barrier in at least one of the electrodes. In general, a relatively small amount of energy may be required to maintain the plasma (about 100 mW-about 10 W per cavity). Visually, a set of plasma jets are directed (projected) from the bottom of the set of holes toward the substrate.

The use of a micro-hollow architecture with a dielectric layer allows the cleaning device to provide a substantially high degree of ionization, substantially low contamination by cathode material, and a reduced likelihood of arcing. By limiting exposure time, a RFMHCD cleaning device can substantially maintain a high etching rate without damaging the substrate (i.e., edge removal, etc.). In addition, a lack of a sophisticated vacuum system may substantially reduce operational and amortizations costs, as well as potential maintenance problems. For example, very large substrates (i.e., LCD panel, etc.) tend to require larger chambers in which to process, which also tend to be difficult to control under vacuum conditions. Subsequently, minimizing the used of a vacuum may significantly reduce costs and increase yield.

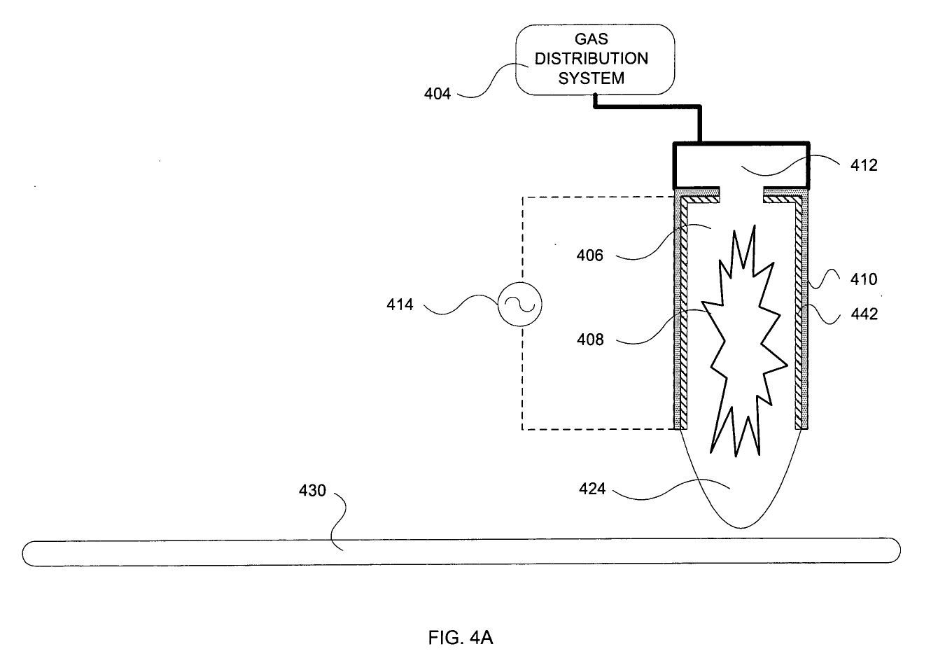

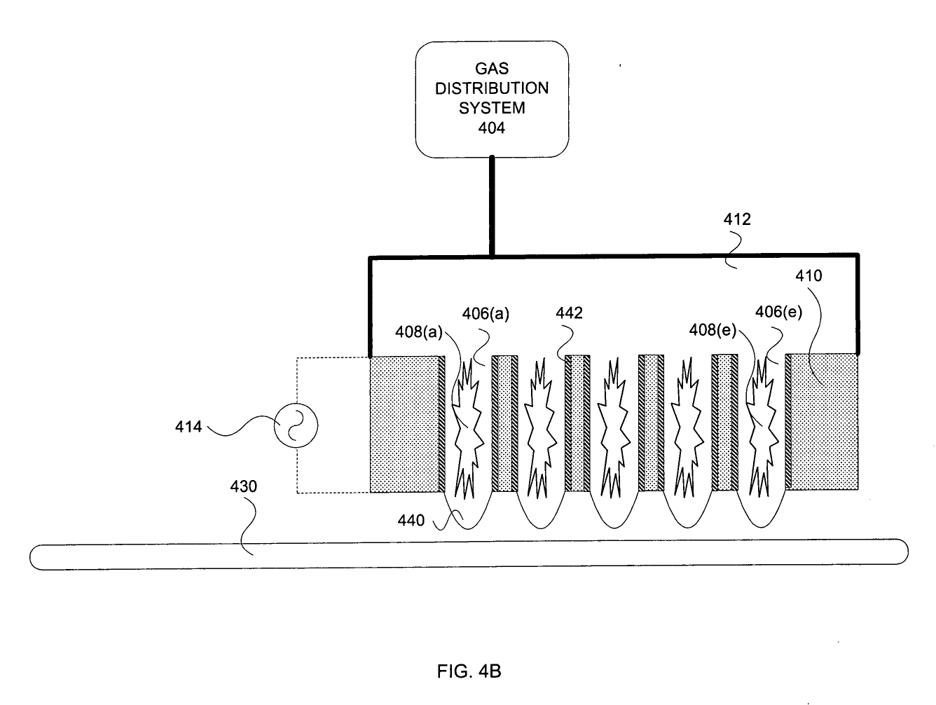

FIGS. 4A-B show a set of simplified diagrams of a RF plasma cleaning device including a dielectric are shown, according to an embodiment of the invention. Referring now to FIG. 4A, a simplified diagram of an RF plasma cleaning device with a single cavity is shown, according to one embodiment of the invention. In one embodiment, the RF plasma cleaning device comprises a RFMHCD device. Dielectric material 442 comprising the interior chamber walls may be placed between the RF generator 414 (RF generation device) and the plasma 408. Dielectric 442 allows an RF field, generated by RF generator 414, to penetrate into the discharge chamber cavity 406, without substantially exposing the discharge chamber wall to electrons in the plasma 408, hence reducing the likelihood of arcing. Subsequently, greater concentrations of ion species can be present in the plasma for RIE processes. Generally, an appropriate set of gases is flowed into sealed box 412 for pressurizing from gas distribution system 404. In one embodiment, sealed box 412 is comprised of Teflon. The gases are, in turn, feed into a set of discharge chamber cavity 406, at which point plasma 408 is struck and subsequently protrudes from one end of cavity 406 to etch substrate 430.

In another embodiment, the discharge chamber consumes between about 100 mW and about 10 W. In another embodiment, the discharge chamber consumes about 500 SCCM of He. In another embodiment, each plasma beam can etch a width of between about 0.2 mm and about 2 mm in about 30 seconds. In another embodiment, the RFMHCD cleaning device is substantially stationary and the substrate rotates during the cleaning process.

Referring now to FIG. 4B, a simplified diagram of an RF plasma cleaning device with a set of cavities is shown, according to one embodiment of the invention. Like FIG. 4A, the RF plasma cleaning device can comprises a RFMHCD device. As before, a dielectric material 442 may be placed between the RF generator and the plasma gas, allowing greater concentrations of ion species in plasma 408 for RIE processes

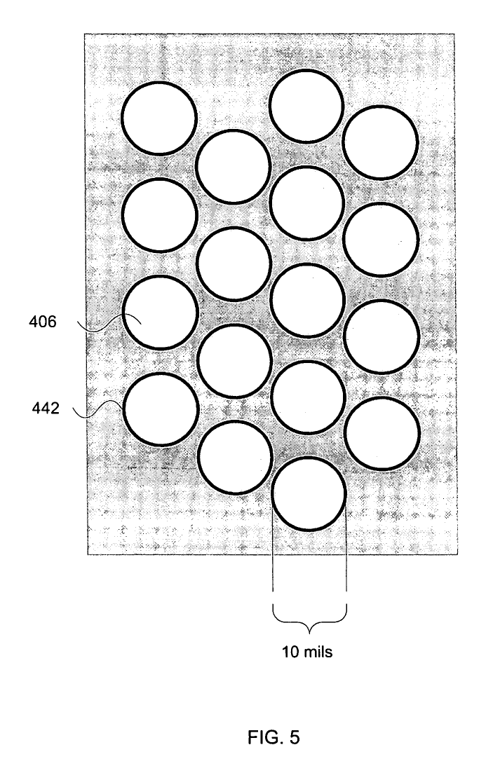

Referring now to FIG. 5, the RFMHCD cleaning device of FIG. 4 is shown, from a view that is parallel to the discharge chambers, according to one embodiment of the invention. As previously state, a dielectric material 442 may be placed between the RF generator and the plasma gas within discharge chamber cavity 406. In one embodiment, the diameter of discharge chamber cavity 406 is about 10 mils.

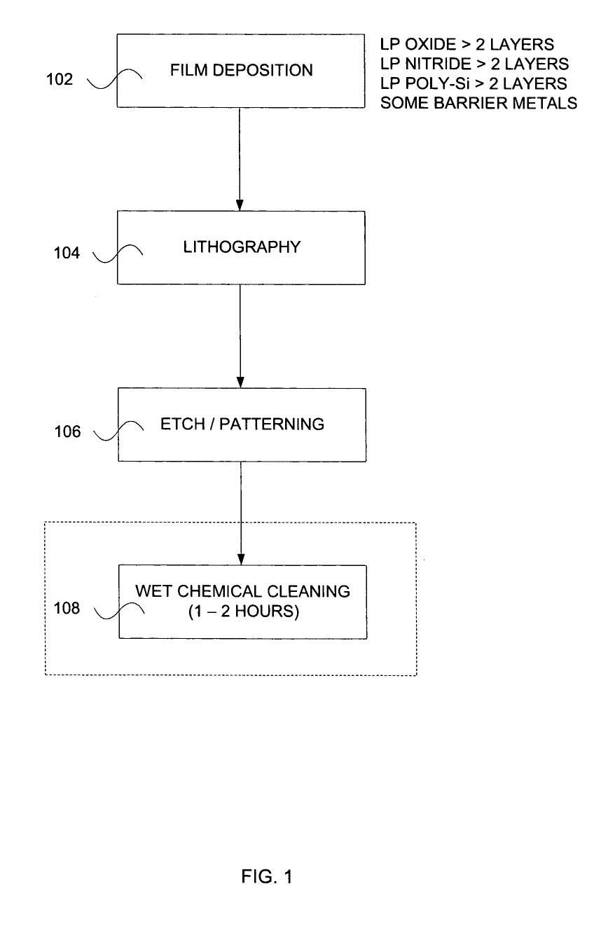

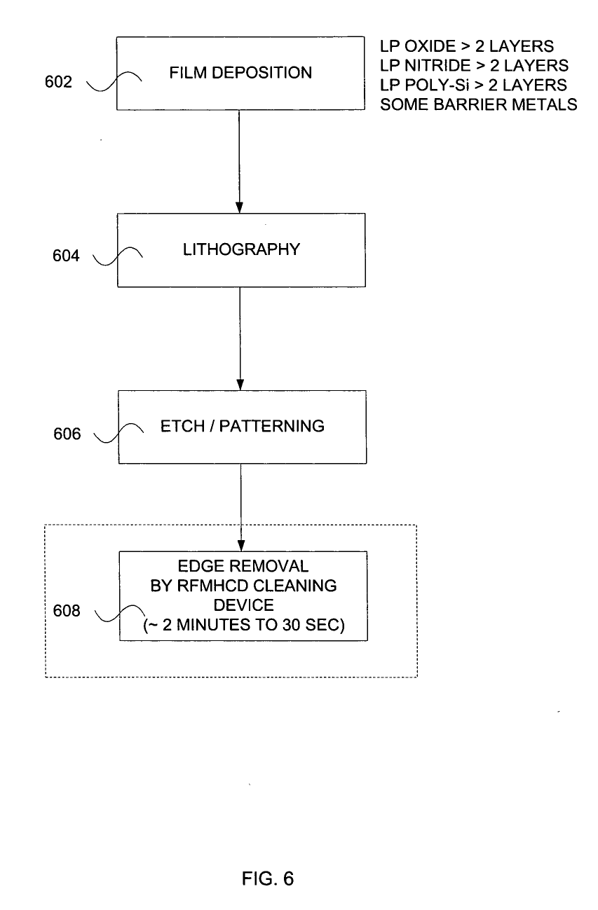

Referring now to FIG. 6, a simplified substrate manufacturing process is shown, according to one embodiment of the invention. Initially, a set of LP (low pressure) oxides, nitrides, poly-Si, and some barrier materials are deposited on the substrate at step 602. Next, a set of substrate masks is patterned in a lithography process, at step 604. The substrate in then etched and further patterned using chemically dominant etch process, at step 606. However, unlike the wet chemical cleaning process described in FIG. 1 which can consume from between about 1 to about 2 hours, a RFMHCD cleaning device can process a substrate between about 30 seconds to about 2 minutes per substrate, at step 608.

Furthermore, this invention is substantially distinguished from the prior art in several respects. For example, this apparatus does not treat the surface of particles by plasma-activated gas species to modify the particle surfaces, nor does it reduce the likelihood of arcing through the use of slots, high flow velocities, and an alumina cap.

While this invention has been described in terms of several preferred embodiments, there are alterations, permutations, and equivalents which fall within the scope of this invention. For example, although the present invention has been described in connection with Lam Research plasma processing systems (e.g., Exelan™, Exelan™ HP, Exelan™ HPT, 2300™, Versys™ Star, etc.), other plasma processing systems may be used. This invention may also be used with substrates of various diameters (e.g., 200 mm, 300 mm, LCD, etc.).

Advantages of the invention include the use of an atmospheric plasma in a reactive ion etch (RIE) process to optimally clean a substrate. Additional advantages include the ability to easily integrate the RFMHCD cleaning device into an in-situ wet cleaning process, and the optimization of a substrate manufacturing process.

Having disclosed exemplary embodiments and the best mode, modifications and variations may be made to the disclosed embodiments while remaining within the subject and spirit of the invention as defined by the following claims.

1. An apparatus for cleaning a substrate in a reactive ion etch process, said apparatus being configured to produce an atmospheric plasma using a RF generation device, comprising:
a plasma forming chamber including a cavity defined by a set of interior chamber walls comprised of a dielectric material;
an atmospheric plasma generated by said RF generation device, said atmospheric plasma protruding from a first end of said cavity to clean said substrate.

2. The apparatus of claim 1 further including a gas distribution system coupled to a second end of said cavity.

3. The apparatus of claim 2, wherein a sealed box for pressurizing a set of gases is coupled between said gas distribution system and said second end.

4. The apparatus of claim 3, wherein said sealed box comprises Teflon.

5. The apparatus of claim 1, wherein atmospheric plasma comprises CF₄.

6. The apparatus of claim 1, wherein atmospheric plasma comprises SF₆.

7. The apparatus of claim 1, wherein atmospheric plasma comprises C₂F₆.

8. The apparatus of claim 1, wherein atmospheric plasma comprises O₂.

9. The apparatus of claim 1, wherein atmospheric plasma comprises N₂.

10. The apparatus of claim 1, further including a set of active ion species.

11. The apparatus of claim 1, wherein said set of active ion species comprises greater than 5% of said atmospheric plasma.

12. (canceled)

13. The apparatus of claim 1, where each of said plasma forming chambers requires between about 100 mW and about 10 W per cavity.

13. The apparatus of claim 1, where said cavity is a micro-hollow cathode discharge chamber.

14. An apparatus for cleaning a substrate in a reactive ion etch process, said apparatus being configured to produce an atmospheric plasma using a RF generation device, comprising:
a set of plasma forming chambers, each of said set of plasma forming chambers including a cavity defined by a set of interior chamber walls comprised of a dielectric material;
an atmospheric plasma generated by said RF generation device, said atmospheric plasma protruding from a first end of said cavity to clean said substrate.

15. The apparatus of claim 14 further including a gas distribution system coupled to a second end of said cavity.

16. The apparatus of claim 15, wherein a sealed box for pressurizing a set of gases is coupled between said gas distribution system and said second end.

16. (canceled)

17. The apparatus of claim 15, wherein atmospheric plasma comprises CF₄.

18. The apparatus of claim 15, wherein atmospheric plasma comprises SF₆.

19. The apparatus of claim 15, wherein atmospheric plasma comprises C₂F₆.

20. The apparatus of claim 15, wherein atmospheric plasma comprises O₂.

21. The apparatus of claim 15, wherein atmospheric plasma comprises N₂.

22. The apparatus of claim 15, further including a set of active ion species.

23. The apparatus of claim 15, wherein said set of active ion species comprises greater than 5% of said atmospheric plasma.

24. (canceled)

25. The apparatus of claim claim 15, where each of said plasma forming chambers requires between about 100 mW and about 10 W per cavity.

26. The apparatus of claim claim 15, where said cavity is a micro-hollow cathode discharge chamber.

27. An apparatus for cleaning a substrate in a reactive ion etch process, said apparatus being configured to produce an atmospheric plasma using a RF generation device, comprising:
a set of plasma forming chambers, each of said set of plasma forming chambers including a cavity defined by a set of interior chamber walls comprised of a dielectric material;
a gas distribution system coupled to a second end of said cavity;
a sealed box for pressurizing a set of gases coupled between said gas distribution system and said second end;
an atmospheric plasma generated by said RF generation device, said atmospheric plasma protruding from a first end of said cavity to clean said substrate.

28. The apparatus of claim 15, wherein said sealed box comprises Teflon.
